(19) United States
(12) Patent Application Publication
(10) Pub. No.: US 2009/0293943 A1
(43) Pub. Date: Dec. 3, 2009

(54) Silicon Film Deposition Method Utilizing a Silent Electric Discharge

(75) Inventors: Alan E. Delahoy, Rocky Hill, NJ (US); Masud Akhtar, Lawrenceville, NJ (US)

Correspondence Address: BROOKS KUSHMAN P.C., 1000 TOWN CENTER, TWENTY-SECOND FLOOR, SOUTHFIELD, MI, 48075, US

(73) Assignee: ENERGY PHOTOVOLTAICS, INC., Lawrenceville, NJ (US)

(21) Appl. No.: 12/466,137

(22) Filed: May 14, 2009

Related U.S. Application Data
(60) Provisional application No. 61/053,034, filed on May 14, 2008.

(51) Int. Cl. H01L 31/04; B05D 3/14; C01B 33/02

(52) U.S. Cl. 136/252; 427/563; 423/349

(57) ABSTRACT

A method for depositing a silicon film on a substrate includes a step of flowing a first silicon-containing gaseous composition through an electric discharge generated to form a second silicon-containing composition that is different than the first silicon-containing composition. The second composition is directed into a deposition chamber to form a silicon-containing film on one or more substrates positioned within the deposition chamber. The formation of crystalline silicon is controlled by the temperature of the deposition.

### CROSS-REFERENCE TO RELATED APPLICATIONS

This application claims the benefit of U.S. provisional application Ser. No. 61/053,034 filed May 14, 2008.

### BACKGROUND OF THE INVENTION

1. Field of the Invention

In at least one aspect, the present invention relates to a method and apparatus for depositing silicon films on a substrate.

2. Background Art

A significant portion of solar cell technology is based around the photovoltaic properties of silicon. In particular, crystalline, polycrystalline, and amorphous silicon have all been used to fabricate photovoltaic devices. Although photovoltaic technology is progressing, the costs of forming the requisite silicon precursors remains high. Moreover, many silicon precursors present safety concerns necessitating the implementation of expensive chemical handling equipment.

Accordingly, for at least these reasons, there is a need for methods for forming and handling silicon precursors with reduced associated costs.

### SUMMARY OF THE INVENTION

The present invention solves one or more problems of the prior art by providing in at least one aspect a method for depositing a silicon film on a substrate. The method of this embodiment includes a step of flowing a first silicon- containing gaseous composition through an electric discharge in an electric discharge chamber generated to form a second silicon-containing composition that is different than the first silicon-containing composition. The second composition is directed into a deposition chamber to form a silicon-containing film on one or more substrates positioned within the deposition chamber. In accordance with the present invention, at least a portion of a silicon-containing monomeric feedstock is converted to a polymer in the electric discharge chamber. The polymer is then transported to the deposition chamber. Advantageously, the polymer transported thereto allow for the deposition of crystalline silicon films (e.g., polycrystalline or various microcrystalline silicon films) at a low temperature than deposition from just the monomer. Moreover, the polycrystalline silicon deposition rate is enhanced by utilization of the generated silicon-containing polymer. Advantageously, the silicon films made by the method of this embodiment may be incorporated into photovoltaic devices such as solar cells and into silicon-based electronic devices.

### BRIEF DESCRIPTION OF THE DRAWINGS

FIG. 1 is a schematic illustration of a deposition system having an electric discharge reactor incorporated therein;

FIG. 2 is a longitudinal cross section of the electric discharge chamber used in variations of the present invention; and

FIG. 3 provides a cross section of the electric discharge chamber that is perpendicular to the longitudinal cross section of FIG. 2.

### DETAILED DESCRIPTION OF THE PREFERRED EMBODIMENT(S)

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

Throughout this application, where publications are referenced, the disclosures of these publications in their entireties are hereby incorporated by reference into this application to more fully describe the state of the art to which this invention pertains.

A silent electric discharge is an electric discharge that is generated across a gap that is typically quite small (e.g, less than 5 mm). Sometimes in such discharges, light or audible sound is not observed.

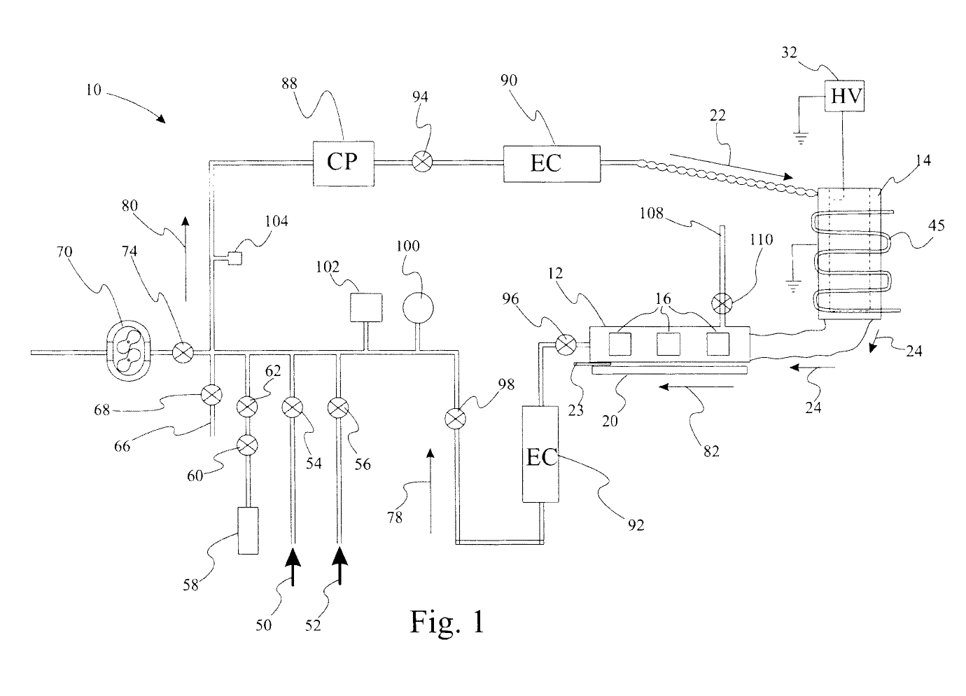

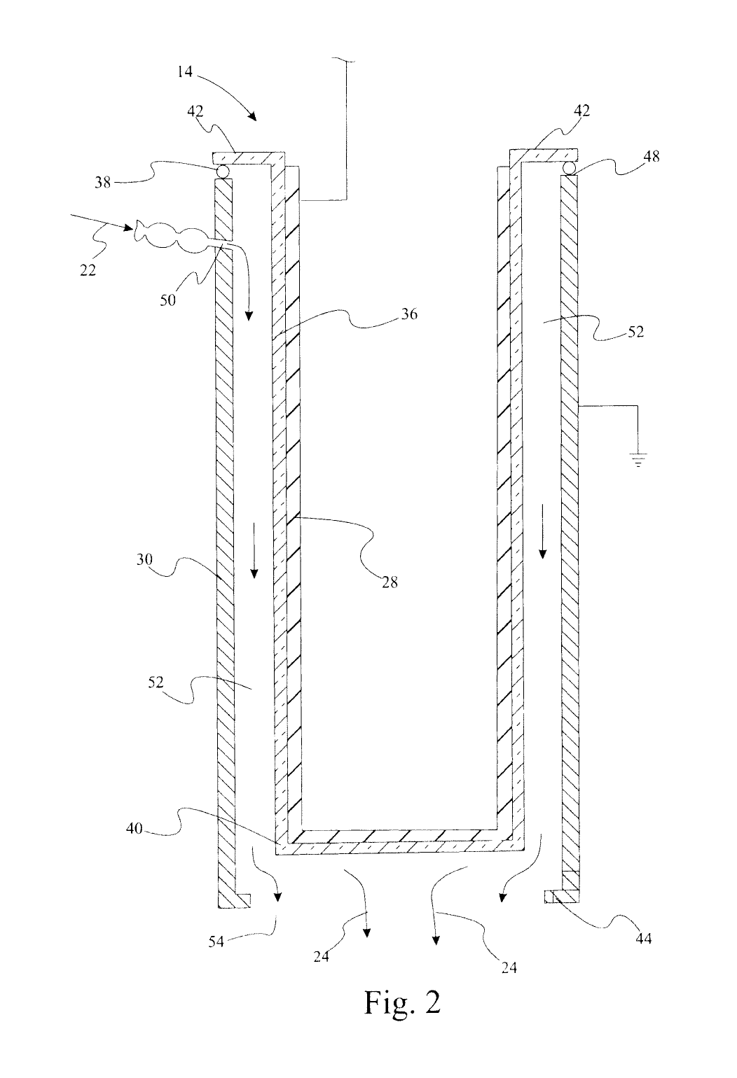

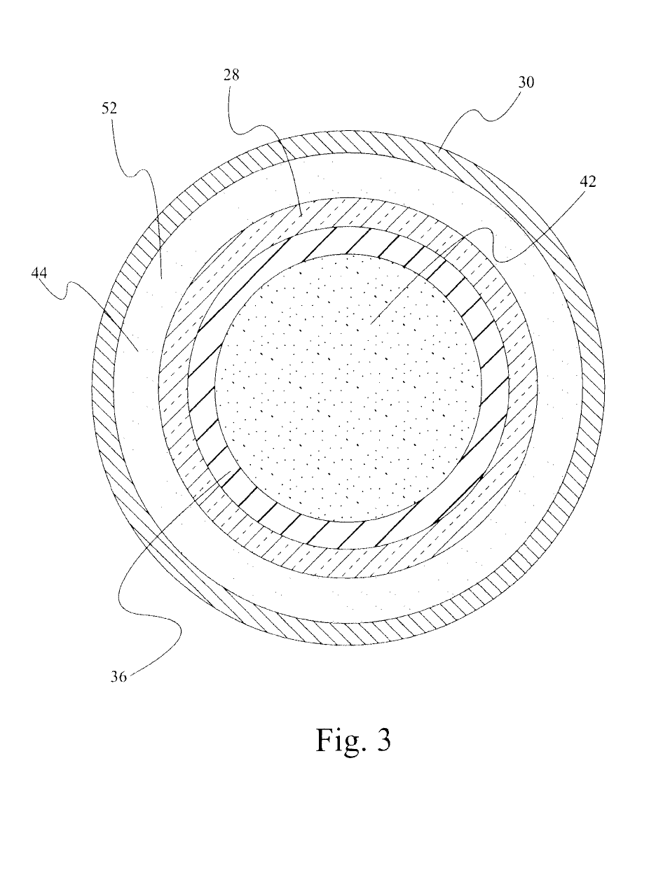

With reference to FIGS. 1, 2, and 3, a crystalline silicon deposition system having an integral electric discharge chamber is described. The deposition system of this embodiment is useful for forming crystalline silicon films. Typically, such films are polycrystalline or microcrystalline. FIG. 1 is a schematic illustration of the deposition system. FIG. 2 is a longitudinal cross section of the electric discharge chamber. FIG. 3 provides a cross section of the electric discharge chamber that is perpendicular to the longitudinal cross section of FIG. 2. Deposition system 10 includes deposition chamber 12 and electric discharge chamber 14. Samples 16 are positioned in depositions chamber 12. Samples 16 are heated by heater 20. Any suitable heater 20 may be deployed for this purpose (e.g, resistive, RF, etc.) . The temperature of deposition chamber 12 is monitored by thermocouple 23. In one variation, substrates are heated to a temperature from about 400 to about 600° C. In another variation, substrates 16 are heated to a temperature from about 600 to about 800° C.

Still referring to FIGS. 1, 2, and 3, deposition chamber 12 is constructed from a material that can withstand the desired deposition temperatures. Such materials will depend on the crystalline silicon film deposition temperature and the chemical reactivity of the second silicon-containing composition. Examples of useful materials include, but are not limited to, quartz, boron nitride, zirconia, stainless steels, glass, ceramic refractories, etc. During operation of the present invention, a first silicon-containing gaseous composition is flowed through an electric discharge generated in electric discharge chamber 14 in the direction indicated by arrow 22. A second silicon-containing composition is formed therein that is different than the first silicon-containing composition. Arrow 24 indicates the flow direction of the second silicon-containing composition. In one variation of the present invention, the electric discharge is a silent electric discharge. The electric discharge brings about a modification in one or more components of the first silicon-containing composition.

Electric discharge chamber 14 includes electrodes 28, 30. Electrodes 28 and 30 are necessarily at different electrical potentials. Typically, the potential difference between electrodes 28 and 30 is from about 5 KV to about 30 KV. In a refinement of the present embodiment, the potential difference between electrodes 28 and 30 is from about 8 KV to about 20 KV. In yet another variation, of the present embodiment, the potential difference between electrodes 28 and 30 is from about 8 KV to about 12 KV. DC voltage source 32 is deployed to provide the necessary potential differences between electrodes 28 and 30. In order to maintain the potential difference and of course to prevent shorting, electrodes 28, 30 must be isolated from each other. Insulating barrier 36 and O-ring 38 provide the necessary separation. FIGS. 2 and 3 depict a variation in which a quartz or glass tube is used for barrier 36. In such a variation, barrier 36 includes end cap 40 and flange 42 which seals to O-ring 38. In the variation of FIGS. 2 and 3, electrode 30 is formed from a metal tube with end cap 44. This metal tube also seals to O-ring 38 at position 48.

First silicon-containing composition 22 enters electric discharge chamber 14 via entrance port 50, travels through gap region 52, and exits through exit port 54. In one variation of the present embodiment, the first silicon-containing composition comprises a silicon halide. Examples of suitable silicon halides include, but are not limited to, SiCl₄, SiCl₃H, SiF₄, SiCl₂H₂, and combinations thereof. In another variation of the present embodiment, the first silicon-containing composition comprises SiH₄, GeH₄, and mixtures thereof.

The electric discharge within gap region 52 initiates various chemical reactions and rearrangements advantageously transforming the first silicon-containing composition into a form that readily forms silicon films at temperatures below about 600° C. In a refinement of the present embodiment, the electric discharge within gap region 52 initiates various chemical reactions and rearrangements advantageously transforming the first silicon-containing composition into a form that readily forms silicon films at temperatures below about 1000° C. In another refinement of the present embodiment, the electric discharge within gap region 52 initiates various chemical reactions and rearrangements advantageously transforming the first silicon-containing composition into a form that readily forms silicon films at temperatures below about 700° C.

With reference to FIG. 1, a variation of delivery of the first silicon-containing composition to electric discharge chamber 14 is provided. Starting materials are introduced into system 10 via input ports 50, 52. Valves 54, 56 are opened when deposition system 10 is to be charged with reacts and closed otherwise. Deposition system 10 may also include cold trap 58 for collecting materials from the system when desired (e.g, unreacted components, spent reactants). Valves 60, 62 are used to control such collections. System 10 may also be vented through vent 66 which is controlled by valve 68. Pump 70 is utilized to evacuate system 10 and provide pressure control when desired. Valve 74 controls pump 70 access to the system. Reactants flow through system 10 in the directions indicated by arrows 78, 80, 82. Flow is maintained by re-circulation pump 88. Expansion chambers 90, 92 are utilized to allow the system to contain enough materials to deposit films on the substrates without the need for recharging. Auxiliary valves 94, 96, 98 are used to close off various sections of deposition system 10. Finally, gauges 100, 102 are used to monitor the system vacuum and pressure. Typically, the pressures are from about 0.01 atm to about 1.5 atm. During normal operation, system 10 is evacuated via pump 70. Valve 74 is then closed off. Valves 54, 56 are opened and reactants charged to the system. These reactants include one or more of the silicon-containing compounds set forth above. Hydrogen may also be provided during this charging as well as an inert gas if desired. Valve 54, 56 are closed. Re-circulation pump 88 moves the reactants through the system during deposition. It should be appreciated that reactants may circulate a number of times through the system thereby increasing film yield from the initially charged reactants. Deposition system 10 also includes pressure release valve 104 to prevent an undesired pressure buildup.

In a variation of the present invention, a dopant containing composition may be introduced into deposition chamber 12 to form doped crystalline silicon films is desired. Such dopants may be introduce via inlet. Suitable dopants include, but are not limited to, phosphine and diborane. Suitable dopants include phosphine and diborane.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method for depositing a silicon film on a substrate in a deposition system having an electric discharge chamber is fluid communication with a deposition chamber, the method comprising:
a) flowing a first silicon-containing gaseous composition through an electric discharge generated in the electric discharge chamber to form a second silicon-containing composition, the second silicon-containing composition being different than the first silicon-containing composition; and
b) directing the second silicon-containing composition into the deposition chamber, the deposition chamber being at a sufficient temperature to form a silicon-containing film on one or more substrates positioned within the deposition chamber.

2. The method of claim 1 wherein the electric discharge is a silent electric discharge.

3. The method of claim 1 further including a step of introducing a dopant in the deposition chamber to form a doped crystalline film.

4. The method of claim 1 wherein the first silicon containing composition comprises a silicon halide.

5. The method of claim 1 wherein the first silicon-containing composition comprises SiCl₄, SiCl₃H, SiF₄, SiCl₂H₂, and combinations thereof.

6. The method of claim 1 wherein the first silicon-containing composition comprises SiH₄, GeH₄, and mixtures thereof.

7. The method of claim 1 wherein the substrates are heated to a temperature from about 400 to about 600° C.

8. The method of claim 1 wherein the substrates are heated to a temperature from about 600 to about 800° C.

9. The method of claim 1 wherein the electric discharge chamber comprises a first electrode and a second electrode.

10. The method of claim 1 wherein there a potential difference between the first and second from about 5 KV to about 30 KV.

11. The method of claim 1 wherein the first silicon-containing composition includes a carrier gas.

12. A silicon film made by the method of claim 1

13. A photovoltaic device incorporating the silicon film of claim 12.

14. The photovoltaic device of claim 12 wherein the photovoltaic device is a solar cell.

15. A method for depositing a silicon film on a substrate in a deposition system having an electric discharge chamber is fluid communication with a deposition chamber, the method comprising:
a) flowing a silicon halide-containing gaseous composition through an electric discharge generated in the electric discharge chamber to form a second silicon-containing composition, the second silicon-containing composition being different than the first silicon-containing composition; and
b) directing the second silicon-containing composition into the deposition chamber, the deposition chamber being at a sufficient temperature to form a silicon-containing film on one or more substrates positioned within the deposition chamber.

16. The method of claim 15 wherein the first silicon-containing composition comprises SiCl₄, SiCl₃H, SiF₄, SiCl₂H₂, and combinations thereof.
